(19) United States
(12) Patent Application Publication
(10) Pub. No.: US 2021/0345711 A1
(43) Pub. Date: Nov. 11, 2021

(54) THIN FILM LAYERS AND COMPOSITE STRUCTURES FOR VIRUS CONTROL

(71) Applicant: SAINT-GOBAIN PERFORMANCE PLASTICS CORPORATION, Solon, OH (US)

(72) Inventors: William C. O'ROURKE, La Jolla, CA (US); Robrecht Moerkerke, Kortrijk (BE); Christy De Meyer, San Diego, CA (US); Sharvanti Pinglay, San Diego, CA (US)

(21) Appl. No.: 17/306,186

(22) Filed: May 3, 2021

Related U.S. Application Data
(60) Provisional application No. 63/020,807, filed on May 6, 2020.

(51) Int. Cl. A41D 13/11; C23C 14/20; A01N 59/16

(52) U.S. Cl. CPC A41D 13/1192; A41D 13/1184; A01N 59/16; C23C 14/20

(57) ABSTRACT

The present disclosure relates to an antiviral thin film layer that may include a metallic material. The antiviral thin film layer may have a VLT of at least about 60%. The antiviral thin film layer may further have an influenza A subtype H1N1 antiviral rating (H1N1 antiviral rating) of not greater than about 360 minutes, where the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

### CROSS-REFERENCE TO RELATED APPLICATION(S)

This application claims priority under 35 U.S.C. § 119(e) to U.S. Provisional Patent Application No. 63/020,807, entitled “THIN FILM LAYERS AND COMPOSITE STRUCTURES FOR VIRUS CONTROL,” by William C. O′ROURKE et al., filed May 6, 2020, which is assigned to the current assignee hereof and is incorporated herein by reference in its entirety.

### FIELD OF THE DISCLOSURE

The present disclosure relates to thin film layers having anti-viral properties and composite structures that include such thin film layers having anti-viral properties.

### BACKGROUND

Various viral diseases, in particular respiratory viral diseases spread through contamination of a surface where the virus remains active until it is passed on to another living organism. Accordingly, thin film layers that can be applied to surfaces, in particular, surfaces located in medical buildings or on medical equipment, and which have antiviral properties would be desirable.

### SUMMARY

According to a first aspect, an antiviral thin film lay may include a metallic material. The antiviral thin film layer may have a VLT of at least about 60%. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to another aspect, a composite structure may include a substrate and an antiviral thin film layer overlying a surface of the substrate. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to yet another aspect, a face shield may include a substrate and an antiviral thin film layer overlying a surface of the substrate. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to still another aspect, an antiviral thin film lay may include a metallic material. The antiviral thin film layer may have a VLT of at least about 60%. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to another aspect, a composite structure may include a substrate and an antiviral thin film layer overlying a surface of the substrate. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to yet another aspect, a face shield may include a substrate and an antiviral thin film layer overlying a surface of the substrate. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to still another aspect, an antiviral thin film lay may include a metallic material. The antiviral thin film layer may have a VLT of at least about 60%. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to another aspect, a composite structure may include a substrate and an antiviral thin film layer overlying a surface of the substrate. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to yet another aspect, a face shield may include a substrate and an antiviral thin film layer overlying a surface of the substrate. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to still another aspect, an antiviral thin film lay may include a metallic material. The antiviral thin film layer may have a VLT of at least about 60%. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

According to another aspect, a composite structure may include a substrate and an antiviral thin film layer overlying a surface of the substrate. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

According to yet another aspect, a face shield may include a substrate and an antiviral thin film layer overlying a surface of the substrate. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

According to another aspect, a method of forming an antiviral thin film layer may include depositing a metallic material on a surface to form the antiviral thin film layer. The antiviral thin film lay may include a metallic material. The antiviral thin film layer may have a visible light transmittance (VLT) of at least about 60%. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to another aspect, a method of forming a composite structure may include providing a substrate and depositing a metallic material on a surface of the substrate to form an antiviral thin film layer overlying the surface of the substrate. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to another aspect, a method of forming a face shield may include providing a substrate and depositing a metallic material on a surface of the substrate to form an antiviral thin film layer overlying the surface of the substrate. The antiviral thin film layer may further have an influenza A subtype H1N1 antiviral rating (H1N1 antiviral rating) of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

According to another aspect, a method of forming an antiviral thin film layer may include depositing a metallic material on a surface to form the antiviral thin film layer. The antiviral thin film lay may include a metallic material. The antiviral thin film layer may have a VLT of at least about 60%. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to another aspect, a method of forming a composite structure may include providing a substrate and depositing a metallic material on a surface of the substrate to form an antiviral thin film layer overlying the surface of the substrate. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to another aspect, a method of forming a face shield may include providing a substrate and depositing a metallic material on a surface of the substrate to form an antiviral thin film layer overlying the surface of the substrate. The antiviral thin film layer may further have an influenza A subtype H3N2 antiviral rating (H3N2 antiviral rating) of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

According to another aspect, a method of forming an antiviral thin film layer may include depositing a metallic material on a surface to form the antiviral thin film layer. The antiviral thin film lay may include a metallic material. The antiviral thin film layer may have a VLT of at least about 60%. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to another aspect, a method of forming a composite structure may include providing a substrate and depositing a metallic material on a surface of the substrate to form an antiviral thin film layer overlying the surface of the substrate. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to another aspect, a method of forming a face shield may include providing a substrate and depositing a metallic material on a surface of the substrate to form an antiviral thin film layer overlying the surface of the substrate. The antiviral thin film layer may further have a feline calicivirus antiviral rating (FCV antiviral rating) of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

According to another aspect, a method of forming an antiviral thin film layer may include depositing a metallic material on a surface to form the antiviral thin film layer. The antiviral thin film lay may include a metallic material. The antiviral thin film layer may have a VLT of at least about 60%. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

According to another aspect, a method of forming a composite structure may include providing a substrate and depositing a metallic material on a surface of the substrate to form an antiviral thin film layer overlying the surface of the substrate. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

According to another aspect, a method of forming a face shield may include providing a substrate and depositing a metallic material on a surface of the substrate to form an antiviral thin film layer overlying the surface of the substrate. The antiviral thin film layer may further have a human coronavirus 229E antiviral rating (HCoV-229E antiviral rating) of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

### BRIEF DESCRIPTION OF THE DRAWINGS

Embodiments are illustrated by way of example and are not limited to the accompanying figures.

FIG. 1 includes an illustration showing a diagram of an antiviral thin film layer according to embodiments described herein;

FIG. 2 includes an illustration showing a diagram of a composite structure according to embodiments described herein;

FIG. 3 includes an illustration showing a diagram of a face shield according to embodiments described herein;

FIG. 4 includes a flow chart showing a method for forming an antiviral thin film layer according to embodiments described herein;

FIG. 5 includes a flow chart showing a method for forming a composite structure according to embodiments described herein; and

FIG. 6 includes a flow chart showing a method for forming a face shield according to embodiments described herein.

Skilled artisans appreciate that elements in the figures are illustrated for simplicity and clarity and have not necessarily been drawn to scale.

### DETAILED DESCRIPTION

The following discussion will focus on specific implementations and embodiments of the teachings. The detailed description is provided to assist in describing certain embodiments and should not be interpreted as a limitation on the scope or applicability of the disclosure or teachings. It will be appreciated that other embodiments can be used based on the disclosure and teachings as provided herein.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Embodiments described herein are generally directed to an antiviral thin film layer. According to particular embodiments, the antiviral thin film layer may include a metallic material and may have a VLT of at least about 60%.

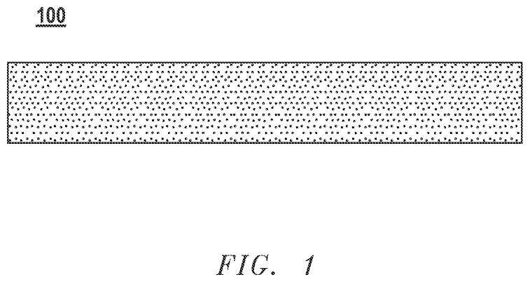

For purposes of illustration, FIG. 1 shows an antiviral thin film layer 100 according to embodiments described herein.

According to certain embodiments, the antiviral thin film layer 100 may have a particular VLT as measured according to ASTM D1003. For example, the antiviral thin film layer 100 may have a VLT of at least about 60%, such as at least about 65% or at least about 70% or at least about 75% or at least about 80% or at least about 85% or at least about 90% or even at least about 95%. It will be appreciated that the VLT of the antiviral thin film layer 100 may be within a range between any of the values noted above. It will be further appreciated that the VLT of the antiviral thin film layer 100 may be any value between any of the values noted above.

According to still other embodiments, the antiviral thin film layer 100 may have a particular H1N1 antiviral rating where the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702. For example, the antiviral thin film layer 100 may have an H1N1 antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H1N1 antiviral rating of the antiviral thin film layer 100 may be within a range between any of the values noted above. It will be further appreciated that the H1N1 antiviral rating of the antiviral thin film layer 100 may be any value between any of the values noted above.

According to yet other embodiments, the antiviral thin film layer 100 may have a particular H3N2 antiviral rating where the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702. For example, the antiviral thin film layer 100 may have an H3N2 antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H3N2 antiviral rating of the antiviral thin film layer 100 may be within a range between any of the values noted above. It will be further appreciated that the H3N2 antiviral rating of the antiviral thin film layer 100 may be any value between any of the values noted above.

According to yet other embodiments, the antiviral thin film layer 100 may have a particular FCV antiviral rating where the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702. For example, the antiviral thin film layer 100 may have an FCV antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the FCV antiviral rating of the antiviral thin film layer 100 may be within a range between any of the values noted above. It will be further appreciated that the FCV antiviral rating of the antiviral thin film layer 100 may be any value between any of the values noted above.

According to yet other embodiments, the antiviral thin film layer 100 may have a particular HCoV-229E antiviral rating where the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702. For example, the antiviral thin film layer 100 may have an HCoV-229E antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the HCoV-229E antiviral rating of the antiviral thin film layer 100 may be within a range between any of the values noted above. It will be further appreciated that the HCoV-229E antiviral rating of the antiviral thin film layer 100 may be any value between any of the values noted above.

According to still other embodiments, the antiviral thin film layer 100 may have a particular antiviral activity R (log¹⁰/cm²) as measured under the ISO 21702 (2019) adapted protocol for a contact time of 180 minutes against human coronavirus HCoV-229E. For example, the antiviral thin film layer 100 may have an antiviral activity R of at least about 1.5, such as at least about 1.6 or at least about 1.7 or at least about 1.8 or at least about 1.9 or at least about 2.0 or at least about 2.1 or at least about 2.2 or at least about 2.3 or at least about 2.4 or at least about 2.5 or at least about 2.6 or at least about 2.7 or at least about 2.8 or at least about 2.9 or at least about 3.0 or even at least about 3.1. It will be appreciated that the antiviral activity R (log¹⁰/cm²) of the antiviral thin film layer 100 may be within a range between any of the values noted above. It will be further appreciated that the antiviral activity R (log¹⁰/cm²) of the antiviral thin film layer 100 may be any value between any of the values noted above.

According to still other embodiments, the antiviral thin film layer 100 may have a particular antiviral activity (%) as measured under the ISO 21702 (2019) adapted protocol for a contact time of 180 minutes against human coronavirus HCoV-229E. For example, the antiviral thin film layer 100 may have an antiviral activity (%) of at least about 99.0%, such as at least about 99.1% or at least about 99.2% or at least about 99.3% or at least about 99.4% or at least about 99.5% or at least about 99.6% or at least about 99.7% or at least about 99.8% or even at least about 99.9%. It will be appreciated that the antiviral activity (%) of the antiviral thin film layer 100 may be within a range between any of the values noted above. It will be further appreciated that the antiviral activity (%) of the antiviral thin film layer 100 may be any value between any of the values noted above.

According to yet other embodiments, the antiviral thin film layer 100 may have a particular average thickness. For example, the antiviral thin film layer 100 may have an average thickness of not greater than about 15 nm, such as, not greater than about 14 nm or not greater than about 13 nm or not greater than about 12 nm or not greater than about 11 nm or not greater than about 10 nm or not greater than about 9 nm or not greater than about 8 nm or not greater than about 7 nm or not greater than about 6 nm or even not greater than about 5 nm. According to yet other embodiments, the antiviral thin film layer 100 may have an average thickness of at least about 0.1 nm or at least about 0.2 nm or at least about 0.3 nm or at least about 0.4 nm or at least about 0.5 nm or at least about 0.6 nm or at least about 0.7 nm or at least about 0.8 nm or at least about 0.9 nm or at least about 1 nm or at least about 2 nm or at least about 3 nm or even at least about 4 nm. It will be appreciated that the average thickness of the antiviral thin film layer 100 may be within a range between any of the minimum and maximum values noted above. It will be further appreciated that the average thickness of the antiviral thin film layer 100 may be any value between any of the minimum and maximum values noted above.

According to still other embodiments, the metallic material of the antiviral thin film layer 100 may include copper, silver, gold, platinum, nickel, zinc, iron, chrome, any combination thereof, or any alloy thereof. According to still other embodiments, the metallic material of the antiviral thin film layer 100 may consist essentially of copper, silver, gold, platinum, nickel, zinc, iron, chrome, any combination thereof, or any alloy thereof. According to still other embodiments, the antiviral thin film layer 100 may be a copper layer, a silver layer, a gold layer, an iron layer, a chrome layer, or a platinum layer.

According to yet other embodiments, the antiviral thin film layer 100 may be a sputtered metallic layer.

According to yet other embodiments, the antiviral thin film layer 100 may be a continuous metallic layer. According to still other embodiments, the antiviral thin film layer 100 may be a non-continuous metallic layer.

According to still other embodiments, the antiviral thin film layer 100 may include multiple metallic layers. For example, the antiviral thin film layer 100 may include at least about 2 metallic layers, such as at least about 3 metallic layers or at least about 4 metallic layers or at least about 5 metallic layers or at least about 6 metallic layers or at least about 7 metallic layers or at least about 8 metallic layers or at least about 9 metallic layers or even at least about 10 metallic layers. It will be appreciated that any of the multiple metallic layers may have any of the characteristics described herein with regard to a metallic layer.

Turning to an alternative embodiment, a composite structure may include a substrate, and an antiviral thin film layer overlying a surface of the substrate. According to particular embodiments, the antiviral thin film layer may include a metallic material and may have a VLT of at least about 60%.

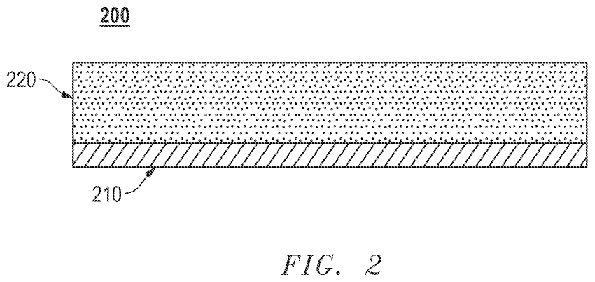

For purposes of illustration, FIG. 2 shows a composite structure 200. According to certain embodiments, the composite structure 200 may include a substrate 210 and an antiviral thin film layer 220 overlying a surface of the substrate 210.

According to certain embodiments, the antiviral thin film layer 220 may have a particular VLT as measured according to ASTM D1003. For example, the antiviral thin film layer 220 may have a VLT of at least about 60%, such as at least about 65% or at least about 70% or at least about 75% or at least about 80% or at least about 85% or at least about 90% or even at least about 95%. It will be appreciated that the VLT of the antiviral thin film layer 220 may be within a range between any of the values noted above. It will be further appreciated that the VLT of the antiviral thin film layer 220 may be any value between any of the values noted above.

According to still other embodiments, the antiviral thin film layer 220 may have a particular H1N1 antiviral rating where the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702. For example, the antiviral thin film layer 220 may have an H1N1 antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H1N1 antiviral rating of the antiviral thin film layer 220 may be within a range between any of the values noted above. It will be further appreciated that the H1N1 antiviral rating of the antiviral thin film layer 220 may be any value between any of the values noted above.

According to yet other embodiments, the antiviral thin film layer 220 may have a particular H3N2 antiviral rating where the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702. For example, the antiviral thin film layer 220 may have an H3N2 antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H3N2 antiviral rating of the antiviral thin film layer 220 may be within a range between any of the values noted above. It will be further appreciated that the H3N2 antiviral rating of the antiviral thin film layer 220 may be any value between any of the values noted above.

According to yet other embodiments, the antiviral thin film layer 220 may have a particular FCV antiviral rating where the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702. For example, the antiviral thin film layer 220 may have an FCV antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the FCV antiviral rating of the antiviral thin film layer 220 may be within a range between any of the values noted above. It will be further appreciated that the FCV antiviral rating of the antiviral thin film layer 220 may be any value between any of the values noted above.

According to yet other embodiments, the antiviral thin film layer 220 may have a particular HCoV-229E antiviral rating where the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702. For example, the antiviral thin film layer 220 may have an HCoV-229E antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the HCoV-229E antiviral rating of the antiviral thin film layer 220 may be within a range between any of the values noted above. It will be further appreciated that the HCoV-229E antiviral rating of the antiviral thin film layer 220 may be any value between any of the values noted above.

According to still other embodiments, the antiviral thin film layer 220 may have a particular antiviral activity R (log¹⁰/cm²) as measured under the ISO 21702 (2019) adapted protocol for a contact time of 180 minutes against human coronavirus HCoV-229E. For example, the antiviral thin film layer 220 may have an antiviral activity R of at least about 1.5, such as at least about 1.6 or at least about 1.7 or at least about 1.8 or at least about 1.9 or at least about 2.0 or at least about 2.1 or at least about 2.2 or at least about 2.3 or at least about 2.4 or at least about 2.5 or at least about 2.6 or at least about 2.7 or at least about 2.8 or at least about 2.9 or at least about 3.0 or even at least about 3.1. It will be appreciated that the antiviral activity R (log¹⁰/cm²) of the antiviral thin film layer 220 may be within a range between any of the values noted above. It will be further appreciated that the antiviral activity R (log¹⁰/cm²) of the antiviral thin film layer 100 may be any value between any of the values noted above.

According to still other embodiments, the antiviral thin film layer 220 may have a particular antiviral activity (%) as measured under the ISO 21702 (2019) adapted protocol for a contact time of 180 minutes against human coronavirus HCoV-229E. For example, the antiviral thin film layer 220 may have an antiviral activity (%) of at least about 99.0%, such as at least about 99.1% or at least about 99.2% or at least about 99.3% or at least about 99.4% or at least about 99.5% or at least about 99.6% or at least about 99.7% or at least about 99.8% or even at least about 99.9%. It will be appreciated that the antiviral activity (%) of the antiviral thin film layer 220 may be within a range between any of the values noted above. It will be further appreciated that the antiviral activity (%) of the antiviral thin film layer 220 may be any value between any of the values noted above.

According to yet other embodiments, the antiviral thin film layer 220 may have a particular average thickness. For example, the antiviral thin film layer 220 may have an average thickness of not greater than about 15 nm, such as, not greater than about 14 nm or not greater than about 13 nm or not greater than about 12 nm or not greater than about 11 nm or not greater than about 10 nm or not greater than about 9 nm or not greater than about 8 nm or not greater than about 7 nm or not greater than about 6 nm or even not greater than about 5 nm. According to yet other embodiments, the antiviral thin film layer 220 may have an average thickness of at least about 0.1 nm or at least about 0.2 nm or at least about 0.3 nm or at least about 0.4 nm or at least about 0.5 nm or at least about 0.6 nm or at least about 0.7 nm or at least about 0.8 nm or at least about 0.9 nm or at least about 1 nm or at least about 2 nm or at least about 3 nm or even at least about 4 nm. It will be appreciated that the average thickness of the antiviral thin film layer 220 may be within a range between any of the minimum and maximum values noted above. It will be further appreciated that the average thickness of the antiviral thin film layer 220 may be any value between any of the minimum and maximum values noted above.

According to still other embodiments, the metallic material of the antiviral thin film layer 220 may include copper, silver, gold, platinum, nickel, zinc, iron, chrome, any combination thereof, or any alloy thereof. According to still other embodiments, the metallic material of the antiviral thin film layer 220 may consist essentially of copper, silver, gold, platinum, nickel, zinc, iron, chrome, any combination thereof, or any alloy thereof. According to still other embodiments, the antiviral thin film layer 220 may be a copper layer, a silver layer, a gold layer, an iron layer, a chrome layer, or a platinum layer.

According to yet other embodiments, the antiviral thin film layer 220 may be a sputtered metallic layer.

According to yet other embodiments, the antiviral thin film layer 220 may be a continuous metallic layer. According to still other embodiments, the antiviral thin film layer 220 may be a non-continuous metallic layer.

According to still other embodiments, the antiviral thin film layer 220 may include multiple metallic layers. For example, the antiviral thin film layer 220 may include at least about 2 metallic layers, such as at least about 3 metallic layers or at least about 4 metallic layers or at least about 5 metallic layers or at least about 6 metallic layers or at least about 7 metallic layers or at least about 8 metallic layers or at least about 9 metallic layers or even at least about 10 metallic layers. It will be appreciated that any of the multiple metallic layers may have any of the characteristics described herein with regard to a metallic layer.

According to certain embodiments, the substrate 210 may have a particular VLT as measured according to ASTM D1003. For example, the substrate 210 may have a VLT of at least about 60%, such as at least about 65% or at least about 70% or at least about 75% or at least about 80% or at least about 85% or at least about 90% or even at least about 95%. It will be appreciated that the VLT of the substrate 210 may be within a range between any of the values noted above. It will be further appreciated that the VLT of the substrate 210 may be any value between any of the values noted above.

According to yet other embodiments, the substrate 210 may include a particular material. For example, the substrate 210 may include a polyethylene terephthalate (PET) material, a polycarbonate material, an acrylic material, a plastic material, or a glass material. According to still other embodiments, the substrate 210 may consist of a polyethylene terephthalate (PET) material, a polycarbonate material, an acrylic material, a plastic material, or a glass material.

According to still other embodiments, the substrate 210 may have a particular average thickness. For example, the substrate 210 may have an average thickness of not greater than about 1.0 mm, such as, not greater than about 0.9 mm or not greater than about 0.8 mm or not greater than bout 0.7 mm or not greater than about 0.6 mm or even not greater than about 0.5 mm. According to yet other embodiments, the substrate 220 may have an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm. It will be appreciated that the substrate 210 may be within a range between any of the minimum and maximum values noted above. It will be further appreciated that the average thickness of the substrate 210 may be any value between any of the minimum and maximum values noted above.

According to certain embodiments, the composite structure 200 may have a particular VLT as measured according to ASTM D1003. For example, the composite structure 200 may have a VLT of at least about 60%, such as at least about 65% or at least about 70% or at least about 75% or at least about 80% or at least about 85% or at least about 90% or even at least about 95%. It will be appreciated that the VLT of the composite structure 200 may be within a range between any of the values noted above. It will be further appreciated that the VLT of the composite structure 200 may be any value between any of the values noted above.

According to still other embodiments, the composite structure 200 may have a particular average thickness. For example, the composite structure 200 may have an average thickness of not greater than about 1.0 mm, such as, not greater than about 0.9 mm or not greater than about 0.8 mm or not greater than bout 0.7 mm or not greater than about 0.6 mm or even not greater than about 0.5 mm. According to yet other embodiments, the composite structure 200 may have an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm. It will be appreciated that the average thickness of the composite structure 200 may be within a range between any of the minimum and maximum values noted above. It will be further appreciated that the average thickness of the composite structure 200 may be any value between any of the minimum and maximum values noted above.

Turning to yet another alternative embodiment, a face shield may include a substrate, and an antiviral thin film layer overlying a surface of the substrate. According to particular embodiments, the antiviral thin film layer may include a metallic material and may have a VLT of at least about 60%.

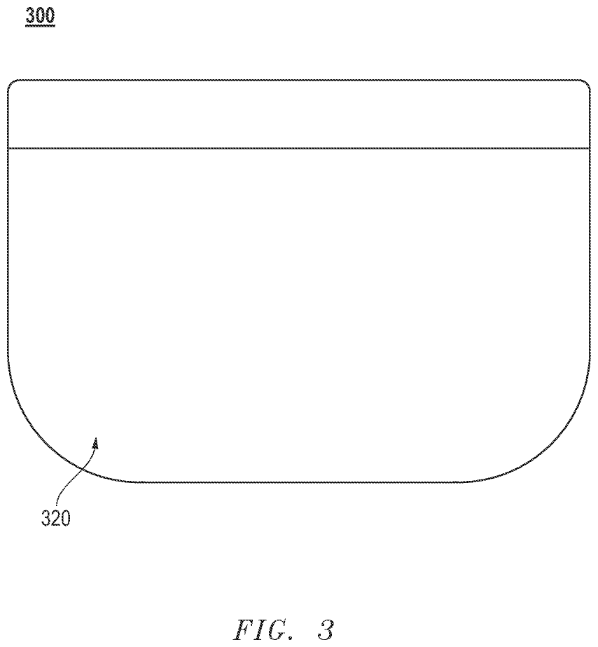

For purposes of illustration, FIG. 3 shows a face shield 300. According to certain embodiments, the face shield 300 may include a substrate (not shown) and an antiviral thin film layer 320 overlying a surface of the substrate.

According to certain embodiments, the antiviral thin film layer 320 may have a particular VLT as measured according to ASTM D1003. For example, the antiviral thin film layer 320 may have a VLT of at least about 60%, such as at least about 65% or at least about 70% or at least about 75% or at least about 80% or at least about 85% or at least about 90% or even at least about 95%. It will be appreciated that the VLT of the antiviral thin film layer 320 may be within a range between any of the values noted above. It will be further appreciated that the VLT of the antiviral thin film layer 320 may be any value between any of the values noted above.

According to still other embodiments, the antiviral thin film layer 320 may have a particular H1N1 antiviral rating where the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702. For example, the antiviral thin film layer 320 may have an H1N1 antiviral rating of not greater than about 360 minutes, such as, not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H1N1 antiviral rating of the antiviral thin film layer 320 may be within a range between any of the values noted above. It will be further appreciated that the H1N1 antiviral rating of the antiviral thin film layer 320 may be any value between any of the values noted above.

According to yet other embodiments, the antiviral thin film layer 320 may have a particular H3N2 antiviral rating where the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702. For example, the antiviral thin film layer 320 may have an H3N2 antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the H3N2 antiviral rating of the antiviral thin film layer 320 may be within a range between any of the values noted above. It will be further appreciated that the H3N2 antiviral rating of the antiviral thin film layer 320 may be any value between any of the values noted above.

According to yet other embodiments, the antiviral thin film layer 320 may have a particular FCV antiviral rating where the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702. For example, the antiviral thin film layer 320 may have an FCV antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the FCV antiviral rating of the antiviral thin film layer 320 may be within a range between any of the values noted above. It will be further appreciated that the FCV antiviral rating of the antiviral thin film layer 320 may be any value between any of the values noted above.

According to yet other embodiments, the antiviral thin film layer 320 may have a particular HCoV-229E antiviral rating where the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702. For example, the antiviral thin film layer 320 may have an HCoV-229E antiviral rating of not greater than about 360 minutes, such as, not greater than about 300 minutes or not greater than about 240 minutes or not greater than about 180 minutes or not greater than about 120 minutes or not greater than about 90 minutes or not greater than about 85 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or even not greater than about 40 minutes. It will be appreciated that the HCoV-229E antiviral rating of the antiviral thin film layer 320 may be within a range between any of the values noted above. It will be further appreciated that the HCoV-229E antiviral rating of the antiviral thin film layer 320 may be any value between any of the values noted above.

According to still other embodiments, the antiviral thin film layer 320 may have a particular antiviral activity R (log¹⁰/cm²) as measured under the ISO 21702 (2019) adapted protocol for a contact time of 180 minutes against human coronavirus HCoV-229E. For example, the antiviral thin film layer 320 may have an antiviral activity R of at least about 1.5, such as at least about 1.6 or at least about 1.7 or at least about 1.8 or at least about 1.9 or at least about 2.0 or at least about 2.1 or at least about 2.2 or at least about 2.3 or at least about 2.4 or at least about 2.5 or at least about 2.6 or at least about 2.7 or at least about 2.8 or at least about 2.9 or at least about 3.0 or even at least about 3.1. It will be appreciated that the antiviral activity R (log¹⁰/cm²) of the antiviral thin film layer 320 may be within a range between any of the values noted above. It will be further appreciated that the antiviral activity R (log¹⁰/cm²) of the antiviral thin film layer 320 may be any value between any of the values noted above.

According to still other embodiments, the antiviral thin film layer 320 may have a particular antiviral activity (%) as measured under the ISO 21702 (2019) adapted protocol for a contact time of 180 minutes against human coronavirus HCoV-229E. For example, the antiviral thin film layer 320 may have an antiviral activity (%) of at least about 99.0%, such as at least about 99.1% or at least about 99.2% or at least about 99.3% or at least about 99.4% or at least about 99.5% or at least about 99.6% or at least about 99.7% or at least about 99.8% or even at least about 99.9%. It will be appreciated that the antiviral activity (%) of the antiviral thin film layer 320 may be within a range between any of the values noted above. It will be further appreciated that the antiviral activity (%) of the antiviral thin film layer 320 may be any value between any of the values noted above.

According to yet other embodiments, the antiviral thin film layer 320 may have a particular average thickness. For example, the antiviral thin film layer 320 may have an average thickness of not greater than about 15 nm, such as, not greater than about 14 nm or not greater than about 13 nm or not greater than about 12 nm or not greater than about 11 nm or not greater than about 10 nm or not greater than about 9 nm or not greater than about 8 nm or not greater than about 7 nm or not greater than about 6 nm or even not greater than about 5 nm. According to yet other embodiments, the antiviral thin film layer 320 may have an average thickness of at least about 0.1 nm or at least about 0.2 nm or at least about 0.3 nm or at least about 0.4 nm or at least about 0.5 nm or at least about 0.6 nm or at least about 0.7 nm or at least about 0.8 nm or at least about 0.9 nm or at least about 1 nm or at least about 2 nm or at least about 3 nm or even at least about 4 nm. It will be appreciated that the average thickness of the antiviral thin film layer 320 may be within a range between any of the minimum and maximum values noted above. It will be further appreciated that the average thickness of the antiviral thin film layer 320 may be any value between any of the minimum and maximum values noted above.

According to still other embodiments, the metallic material of the antiviral thin film layer 320 may include copper, silver, gold, platinum, nickel, zinc, iron, chrome, any combination thereof, or any alloy thereof. According to still other embodiments, the metallic material of the antiviral thin film layer 320 may consist essentially of copper, silver, gold, platinum, nickel, zinc, iron, chrome, any combination thereof, or any alloy thereof. According to still other embodiments, the antiviral thin film layer 320 may be a copper layer, a silver layer, a gold layer, an iron layer, a chrome layer, or a platinum layer.

According to yet other embodiments, the antiviral thin film layer 320 may be a sputtered metallic layer.

According to yet other embodiments, the antiviral thin film layer 320 may be a continuous metallic layer. According to still other embodiments, the antiviral thin film layer 320 may be a non-continuous metallic layer.

According to still other embodiments, the antiviral thin film layer 320 may include multiple metallic layers. For example, the antiviral thin film layer 320 may include at least about 2 metallic layers, such as at least about 3 metallic layers or at least about 4 metallic layers or at least about 5 metallic layers or at least about 6 metallic layers or at least about 7 metallic layers or at least about 8 metallic layers or at least about 9 metallic layers or even at least about 10 metallic layers. It will be appreciated that any of the multiple metallic layers may have any of the characteristics described herein with regard to a metallic layer.

According to certain embodiments, the substrate may have a particular VLT as measured according to ASTM D1003. For example, the substrate may have a VLT of at least about 60%, such as at least about 65% or at least about 70% or at least about 75% or at least about 80% or at least about 85% or at least about 90% or even at least about 95%. It will be appreciated that the VLT of the substrate may be within a range between any of the values noted above. It will be further appreciated that the VLT of the substrate may be any value between any of the values noted above.

According to yet other embodiments, the substrate may include a particular material. For example, the substrate may include a polyethylene terephthalate (PET) material, a polycarbonate material, an acrylic material, a plastic material, or a glass material. According to still other embodiments, the substrate may consist of a polyethylene terephthalate (PET) material, a polycarbonate material, an acrylic material, a plastic material, or a glass material.

According to still other embodiments, the substrate may have a particular average thickness. For example, the substrate may have an average thickness of not greater than about 1.0 mm, such as, not greater than about 0.9 mm or not greater than about 0.8 mm or not greater than bout 0.7 mm or not greater than about 0.6 mm or even not greater than about 0.5 mm. According to yet other embodiments, the substrate may have an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm. It will be appreciated that the substrate may be within a range between any of the minimum and maximum values noted above. It will be further appreciated that the average thickness of the substrate may be any value between any of the minimum and maximum values noted above.

According to certain embodiments, the face shield 300 may have a particular VLT as measured according to ASTM D1003. For example, the face shield 300 may have a VLT of at least about 60%, such as at least about 65% or at least about 70% or at least about 75% or at least about 80% or at least about 85% or at least about 90% or even at least about 95%. It will be appreciated that the VLT of the face shield 300 may be within a range between any of the values noted above. It will be further appreciated that the VLT of the face shield 300 may be any value between any of the values noted above.

According to still other embodiments, the face shield 300 may have a particular average thickness. For example, the face shield 300 may have an average thickness of not greater than about 1.0 mm, such as, not greater than about 0.9 mm or not greater than about 0.8 mm or not greater than bout 0.7 mm or not greater than about 0.6 mm or even not greater than about 0.5 mm. According to yet other embodiments, the face shield 300 may have an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm. It will be appreciated that the average thickness of the face shield 300 may be within a range between any of the minimum and maximum values noted above. It will be further appreciated that the average thickness of the face shield 300 may be any value between any of the minimum and maximum values noted above.

It will be appreciated that and embodiments described herein with regard to an antiviral thin film layer, a composite structure or a face shield may include additional layers. For example, an antiviral thin film layer, a composite structure, or a face shield may include an adhesive layer. According to still other embodiments, an antiviral thin film layer, a composite structure or a face shield may include a liner.

Turning to still another alternative embodiment, a method of forming a composite structure may include depositing a metallic material on a surface to form the antiviral thin film layer.

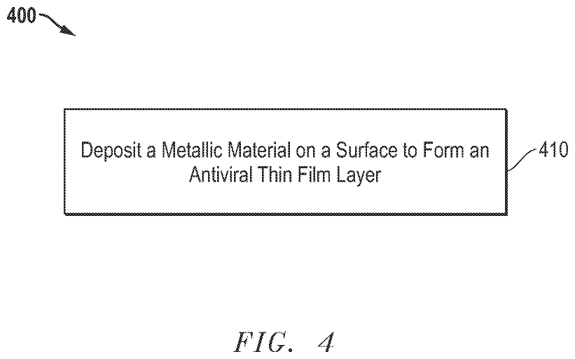

For purposes of illustration, FIG. 4 includes a flow chart showing a method 400 for forming an antiviral thin film layer. According to certain embodiments, the method 400 may include a first step 410 of depositing a metallic material on a surface to form an antiviral thin film layer.

It will be appreciated that the antiviral thin film layer formed according to method 400 may include any of the characteristics or properties of any embodiment of an antiviral thin film layer described herein.

According to certain embodiments, the first step 410 of depositing the metallic material on the surface to form an antiviral thin film layer may include any know deposition method that can form the metallic layer as described herein. According to certain embodiments, depositing the metallic material may include a chemical deposition technique, a physical deposition technique, a sputtering deposition technique, an evaporation deposition technique, or a SolGel deposition technique.

Turning to yet another alternative embodiment, a method of forming a composite structure may include providing a substrate and depositing a metallic material on a surface of the substrate to form an antiviral thin film layer overlying the surface of the substrate.

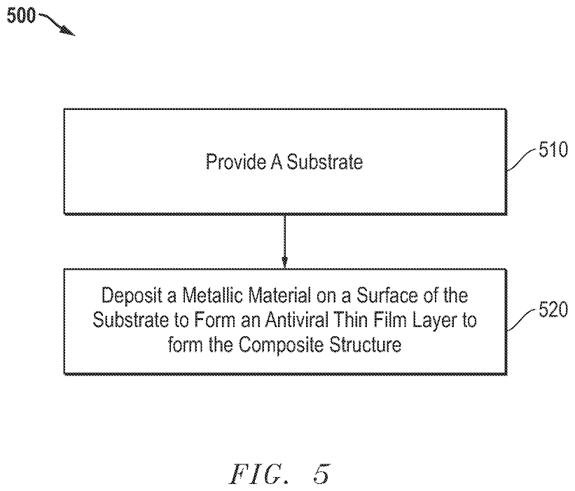

For purposes of illustration, FIG. 5 includes a flow chart showing a method 500 for forming a composite structure. According to certain embodiments, the method 500 may include a first step 510 of providing a substrate, and a second step 520 of depositing a metallic material on a surface of the substrate to form an antiviral thin film layer overlying the surface of the substrate.

It will be appreciated that the substrate, antiviral thin film layer, and composite structure formed according to method 500 may include any of the characteristics or properties of any embodiment of an antiviral thin film layer described herein.

According to certain embodiments, the second step 520 of depositing the metallic material on the surface of the substrate may include any know deposition method that can form the metallic layer as described herein. According to certain embodiments, depositing the metallic material may include a chemical deposition technique, a physical deposition technique, a sputtering deposition technique, an evaporation deposition technique, or a SolGel deposition technique.

Turning to another alternative embodiment, a method of forming a face shield may include providing a substrate and depositing a metallic material on a surface of the substrate to form an antiviral thin film layer overlying the surface of the substrate.

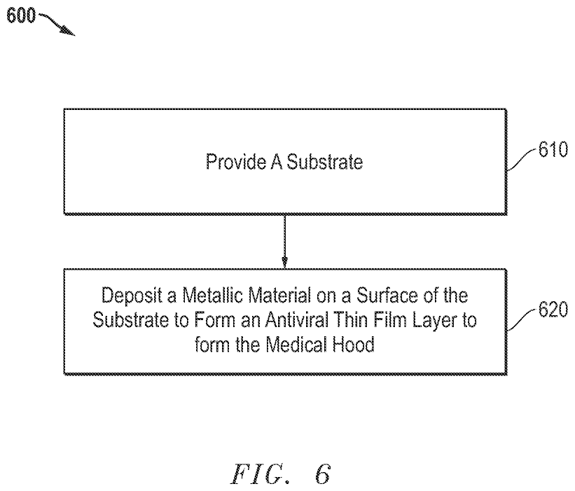

For purposes of illustration, FIG. 6 includes a flow chart showing a method 600 for forming a composite structure. According to certain embodiments, the method 600 may include a first step 610 of providing a substrate, and a second step 620 of depositing a metallic material on a surface of the substrate to form an antiviral thin film layer overlying the surface of the substrate.

It will be appreciated that the substrate, antiviral thin film layer, and face shield formed according to method 600 may include any of the characteristics or properties of any embodiment of an antiviral thin film layer described herein.

According to certain embodiments, the second step 620 of depositing the metallic material on the surface of the substrate may include any know deposition method that can form the metallic layer as described herein. According to certain embodiments, depositing the metallic material may include a chemical deposition technique, a physical deposition technique, a sputtering deposition technique, an evaporation deposition technique, or a SolGel deposition technique.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

Embodiment 1. An antiviral thin film layer comprising a metallic material, wherein the antiviral thin film layer has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 2. A composite structure comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 3. A face shield comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 4. An antiviral thin film layer comprising a metallic material, wherein the antiviral thin film layer has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 5. A composite structure comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 6. A face shield comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 7. An antiviral thin film layer comprising a metallic material, wherein the antiviral thin film layer has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 8. A composite structure comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 9. A face shield comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 10. An antiviral thin film layer comprising a metallic material, wherein the antiviral thin film layer has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 11. A composite structure comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 12. A face shield comprising: a substrate, and an antiviral thin film layer overlying a surface of the substrate, wherein the antiviral thin film layer comprises a metallic material, wherein the composite structure has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 13. The antiviral thin film layer, composite structure, or face shield of any one of embodiments 1-12, wherein the antiviral thin film layer has an H1N1 antiviral rating of not greater than about 330 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 14. The antiviral thin film layer, composite structure, or face shield of any one of embodiments 1-12, wherein the antiviral thin film layer has an H3N2 antiviral rating of not greater than about 330 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 15. The antiviral thin film layer, composite structure, or face shield of any one of embodiments 1-12, wherein the antiviral thin film layer has an FCV antiviral rating of not greater than about 330 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 16. The antiviral thin film layer, composite structure, or face shield of any one of embodiments 1-12, wherein the antiviral thin film layer has an HCoV-229E antiviral rating of not greater than about 330 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 17. The antiviral thin film layer, composite structure, or face shield of any one of embodiments 1-12, wherein the antiviral thin film layer has a VLT of at least about 60% or at least about 65% or at least about 70% or at least about 75% or at least about 80% or at least about 85% or at least about 90% or at least about 95%.

Embodiment 18. The composite structure of any one of embodiments 2, 5, 8, and 11, wherein the composite structure has a VLT of at least about 60% or at least about 65% or at least about 70% or at least about 75% or at least about 80% or at least about 85% or at least about 90% or at least about 95%.

Embodiment 19. The face shield of any one of embodiments 3, 6, 9, and 12, wherein the face shield has a VLT of at least about 60% or at least about 65% or at least about 70% or at least about 75% or at least about 80% or at least about 85% or at least about 90% or at least about 95%.

Embodiment 20. The antiviral thin film layer, composite structure, or face shield of any one of embodiments 1-12, wherein the antiviral thin film layer has an average thickness of not greater than about 15 nm or not greater than about 14 nm or not greater than about 13 nm or not greater than about 12 nm or not greater than about 11 nm or not greater than about 10 nm or not greater than about 9 nm or not greater than about 8 nm or not greater than about 7 nm or not greater than about 6 nm or not greater than about 5 nm.

Embodiment 21. The antiviral thin film layer, composite structure, or face shield of any one of embodiments 1-12, wherein the antiviral thin film layer has an average thickness of at least about 0.1 nm.

Embodiment 22. The antiviral thin film layer, composite structure, or face shield of any one of embodiments 1-12, wherein the metallic material comprises copper, silver, gold, platinum, nickel, zinc, iron, chrome, any combination thereof, or any alloy thereof.

Embodiment 23. The antiviral thin film layer, composite structure, or face shield of any one of embodiments 1-12, wherein the antiviral thin film layer is a copper layer, a silver layer, a gold layer, an iron layer, a chrome layer, or a platinum layer.

Embodiment 24. The antiviral thin film layer, composite structure, or face shield of any one of embodiments 1-12, wherein the antiviral thin film layer is a sputtered metallic layer.

Embodiment 25. The antiviral thin film layer, composite structure, or face shield of any one of embodiments 1-12, wherein the antiviral thin film layer is a continuous metallic layer.

Embodiment 26. The composite structure or face shield of any one of embodiments 2, 3, 5, 6, 8, 9, 11, and 12, wherein the substrate comprises a polyethylene terephthalate (PET) material, a polycarbonate material, an acrylic material, a plastic material, a glass material.

Embodiment 27. The composite structure or face shield of any one of embodiments 2, 3, 5, 6, 8, 9, 11, and 12, wherein the substrate comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 28. The composite structure or face shield of any one of embodiments 2, 3, 5, 6, 8, 9, 11, and 12, wherein the substrate comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

Embodiment 29. The composite structure of any one of embodiments 2, 5, 8, and 11, wherein the composite structure comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 30. The composite structure of any one of embodiments 2, 5, 8, and 11, wherein the composite structure comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

Embodiment 31. The face shield of any one of embodiments 3, 6, 9, and 12, wherein the face shield comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 32. The face shield of any one of embodiments 3, 6, 9, and 12, wherein the face shield comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

Embodiment 33. A method of forming an antiviral thin film layer, wherein the method comprises depositing a metallic material on a surface to form the antiviral thin film layer, wherein the antiviral thin film layer has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 34. A method of forming a composite structure, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 35. A method of forming a face shield, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an H1N1 antiviral rating of not greater than about 360 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702.

Embodiment 36. A method of forming an antiviral thin film layer, wherein the method comprises sputtering a metallic material on a surface to form the antiviral thin film layer, wherein the antiviral thin film layer has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 37. A method of forming a composite structure, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 38. A method of forming a face shield, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an H3N2 antiviral rating of not greater than about 360 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702.

Embodiment 39. A method of forming an antiviral thin film layer, wherein the method comprises sputtering a metallic material on a surface to form the antiviral thin film layer, wherein the antiviral thin film layer has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 40. A method of forming a composite structure, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 41. A method of forming a face shield, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an FCV antiviral rating of not greater than about 360 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702.

Embodiment 42. A method of forming an antiviral thin film layer, wherein the method comprises sputtering a metallic material on a surface to form the antiviral thin film layer, wherein the antiviral thin film layer has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 43. A method of forming a composite structure, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 44. A method of forming a face shield, wherein the method comprises: providing a substrate and depositing a metallic material on a surface of the substrate to form an antiviral thin film layer overlying the surface of the substrate, wherein the antiviral thin film layer comprises a metallic material, wherein the composite structure has a VLT of at least about 60%, and wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

Embodiment 45. The method of any one of embodiments 33-44, wherein depositing the metallic material comprises a chemical deposition technique, a physical deposition technique, a sputtering deposition technique, an evaporation deposition technique, or a SolGel deposition technique.

Embodiment 46. The method of any one of embodiments 33-44, wherein the antiviral thin film layer has an H1N1 antiviral rating of not greater than about 330 minutes, wherein the H1N1 antiviral rating is defined as the amount of time required for H1N1 viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 47. The method of any one of embodiments 33-44, wherein the antiviral thin film layer has an H3N2 antiviral rating of not greater than about 330 minutes, wherein the H3N2 antiviral rating is defined as the amount of time required for H3N2 viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 48. The method of any one of embodiments 33-44, wherein the antiviral thin film layer has an FCV antiviral rating of not greater than about 330 minutes, wherein the FCV antiviral rating is defined as the amount of time required for FCV viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 49. The method of any one of embodiments 33-44, wherein the antiviral thin film layer has an HCoV-229E antiviral rating of not greater than about 330 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702 or not greater than about 300 minutes or not greater than about 240 minutes or not greater than about 180 minutes or not greater than about 120 minutes or not greater than about 90 minutes or not greater than about 80 minutes or not greater than about 75 minutes or not greater than about 70 minutes or not greater than about 65 minutes or not greater than about 60 minutes or not greater than about 55 minutes or not greater than about 50 minutes or not greater than about 45 minutes or not greater than about 40 minutes.

Embodiment 50. The method of any one of embodiments 33-44, wherein the antiviral thin film layer has a VLT of at least about 60% or at least about 65% or at least about 70% or at least about 75% or at least about 80% or at least about 85% or at least about 90% or at least about 95%.

Embodiment 51. The method of any one of embodiments 34, 37, 40, and 43, wherein the composite structure has a VLT of at least about 60% or at least about 65% or at least about 70% or at least about 75% or at least about 80% or at least about 85% or at least about 90% or at least about 95%.

Embodiment 52. The face shield of any one of embodiments 35, 38, 41, and 44, wherein the face shield has a VLT of at least about 60% or at least about 65% or at least about 70% or at least about 75% or at least about 80% or at least about 85% or at least about 90% or at least about 95%.

Embodiment 53. The method of any one of embodiments 33-44, wherein the antiviral thin film layer has an average thickness of not greater than about 15 nm or not greater than about 14 nm or not greater than about 13 nm or not greater than about 12 nm or not greater than about 11 nm or not greater than about 10 nm or not greater than about 9 nm or not greater than about 8 nm or not greater than about 7 nm or not greater than about 6 nm or not greater than about 5 nm.

Embodiment 54. The method of any one of embodiments 33-44, wherein the antiviral thin film layer has an average thickness of at least about 0.1 nm.

Embodiment 55. The method of any one of embodiments 33-44, The method of any one of embodiments 33-44, wherein the metallic material comprises copper, silver, gold, platinum, iron, chrome, or any combination thereof.

Embodiment 56. The method of any one of embodiments 33-44, wherein the antiviral thin film layer is a copper layer, a silver layer, a gold layer, an iron layer, a chrome layer, or a platinum layer.

Embodiment 57. The method of any one of embodiments 33-44, wherein the antiviral thin film layer is a sputtered metallic layer.

Embodiment 58. The method of any one of embodiments 33-44, wherein the antiviral thin film layer is a continuous metallic layer.

Embodiment 59. The method of any one of embodiments 34, 35, 37, 38, 40, 41, 43, and 44, wherein the substrate comprises a polyethylene terephthalate (PET) material, a polycarbonate material, an acrylic material, a plastic material, a glass material.

Embodiment 60. The method of any one of embodiments 34, 35, 37, 38, 40, 41, 43, and 44, wherein the substrate comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 61. The method of any one of embodiments 34, 35, 37, 38, 40, 41, 43, and 44, wherein the substrate comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

Embodiment 62. The composite structure of any one of embodiments 34, 37, 40, and 43, wherein the composite structure comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 63. The composite structure of any one of embodiments 34, 37, 40, and 43, wherein the composite structure comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

Embodiment 64. The face shield of any one of embodiments 35, 38, 41, and 44, wherein the face shield comprises an average thickness of not greater than about 1.0 mm or not greater than about 0.9 mm or not greater than about 0.8 mm or not greater than bout 0.7 mm or not greater than about 0.6 mm or not greater than about 0.5 mm.

Embodiment 65. The face shield of any one of embodiments 35, 38, 41, and 44, wherein the face shield comprises an average thickness of at least about 0.001 mm or at least about 0.005 mm or at least about 0.01 mm or at least about 0.05 mm or at least about 0.1 mm or at least about 0.2 mm or at least about 0.3 mm or at least about 0.4 mm.

### EXAMPLES

The concepts described herein will be further described in the following Examples, which do not limit the scope of the invention described in the claims.

### Example 1

Three sample composite structures S1, S2, and S3 were formed according to embodiments described herein. Each composite structure S1, S2, and S3 included a PET substrate with a thickness of 50 microns, a NiCr adhesive layer with a thickness of 0.5 nm overlying the surface of the PET substrate, and an antiviral think film layer overlying the surface of the NiCr adhesive layer.

The first sample composite structure S1 was formed using sputtering deposition of a NiCr layer at a thickness of 0.5 nm on the PET substrate, then sputtering deposition of a Cu layer at a thickness of 10 nm in the NiCr layer.

The second sample composite structure S2 was formed using sputtering deposition of a NiCr layer at a thickness of 0.5 nm on the PET substrate, then sputtering deposition of a Cu layer at a thickness of 6.8 nm in the NiCr layer.

The third sample composite structure S3 was formed using sputtering deposition of a NiCr layer at a thickness of 5.4 nm on the PET substrate, then sputtering deposition of a Cu layer at a thickness of 10 nm in the NiCr layer.

Performance properties of each sample composite structure S1, S2, and S3 and comparative sample composite structure CS1 were tested and are summarized in Table 1 below. Each sample composite structure S1, S2, and S3 were tested according to ASTM D1003 and protocol ISO 21702 (2019) standard against human coronavirus HCoV-229E for a contact time of 180 minutes. Results were determined by visual reading of cytopathic effects (CPE) and quantified by TCID50 technique on MRCS cells. The summarized performance properties include HCoV-229E Antiviral Activity R, HCoV-229E Antiviral Activity (%), and VLT as described herein.

TABLE 1
Test results of the examples (which were tested for anti-viral properties)

| | HCoV- | | |
|---|---|---|---|
| | 229E | HCoV-229E | |
| | Antiviral | Antiviral | |
| | Activity R | Activity | |
| Sample | (log¹⁰/cm²) | (%) | VLT |
| S1 | 2.1 | 99.21 | 54.2 |
| S1 | 2.1 | 99.21 | 63.5 |
| S2 | 3.1 | 99.92 | 68.5 |

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An antiviral thin film layer comprising a metallic material,
wherein the antiviral thin film layer has a VLT of at least about 60%, and
wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

2. The antiviral thin film layer of claim 1, wherein the antiviral thin film layer has an HCoV-229E antiviral rating of not greater than about 240 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

3. The antiviral thin film layer of claim 1, wherein the antiviral thin film layer has a VLT of at least about 75%.

4. The antiviral thin film layer of claim 1, wherein the antiviral thin film layer has an average thickness of not greater than about 15 nm.

5. The antiviral thin film layer of claim 1, wherein the antiviral thin film layer has an average thickness of at least about 0.1 nm.

6. The antiviral thin film layer of claim 1, wherein the metallic material comprises copper, silver, gold, platinum, nickel, zinc, iron, chrome, any combination thereof, or any alloy thereof.

7. The antiviral thin film layer of claim 1, wherein the antiviral thin film layer is a copper layer, a silver layer, a gold layer, an iron layer, a chrome layer, or a platinum layer.

8. The antiviral thin film layer of claim 1, wherein the antiviral thin film layer is a sputtered metallic layer.

9. The antiviral thin film layer of claim 1, wherein the antiviral thin film layer is a continuous metallic layer.

10. A composite structure comprising:
a substrate, and
an antiviral thin film layer overlying a surface of the substrate,
wherein the antiviral thin film layer comprises a metallic material,
wherein the composite structure has a VLT of at least about 60%, and
wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

11. The composite structure of claim 10, wherein the composite structure has a VLT of at least about 60%.

12. The composite structure of claim 10, wherein the substrate comprises a polyethylene terephthalate (PET) material, a polycarbonate material, an acrylic material, a plastic material, a glass material.

13. The composite structure of claim 10, wherein the substrate comprises an average thickness of not greater than about 1.0 mm.

14. The composite structure of claim 10, wherein the metallic material comprises copper, silver, gold, platinum, nickel, zinc, iron, chrome, any combination thereof, or any alloy thereof.

15. The composite structure of claim 10, wherein the antiviral thin film layer is a copper layer, a silver layer, a gold layer, an iron layer, a chrome layer, or a platinum layer.

16. The composite structure of claim 10, wherein the antiviral thin film layer is a sputtered metallic layer.

17. A face shield comprising:
a substrate, and
an antiviral thin film layer overlying a surface of the substrate,
wherein the antiviral thin film layer comprises a metallic material,
wherein the composite structure has a VLT of at least about 60%, and
wherein the antiviral thin film layer has an HCoV-229E antiviral rating of not greater than about 360 minutes, wherein the HCoV-229E antiviral rating is defined as the amount of time required for HCoV-229E viral activity on a surface of the metallic layer to drop from an initial test concentration placed on the surface of the thin film layer to less than 25.0% of the initial concentration placed on the surface as measured using ISO21702.

18. The face shield of claim 17, wherein the face shield has a VLT of at least about 60%.

19. The face shield of claim 17, wherein the substrate comprises a polyethylene terephthalate (PET) material, a polycarbonate material, an acrylic material, a plastic material, a glass material.

20. The face shield of claim 17, wherein the substrate comprises an average thickness of not greater than about 1.0 mm.
